(19) United States
(12) Patent Application Publication
(10) Pub. No.: US 2009/0050058 A1
(43) Pub. Date: Feb. 26, 2009

(54) PROGRAMMED HIGH SPEED DEPOSITION OF AMORPHOUS, NANOCRYSTALLINE, MICROCRYSTALLINE, OR POLYCRYSTALLINE MATERIALS HAVING LOW INTRINSIC DEFECT DENSITY

(76) Inventor: Stanford R. Ovshinsky, Rochester Hills, MI (US)

Correspondence Address: Kevin L. Bray;Ovshinsky Innovation, LLC., 1050 E. Square Lake Road, Bloomfield Hills, MI, 48304, US

(21) Appl. No.: 12/199,730

(22) Filed: Aug. 27, 2008

Related U.S. Application Data
(63) Continuation-in-part of application No. 11/546,619, filed on Oct. 12, 2006.

(51) Int. Cl. C23C 16/54

(52) U.S. Cl. 118/723 MW; 118/723 I

(57) ABSTRACT

A method and apparatus for the unusually high rate deposition of thin film materials on a stationary or continuous substrate. The method includes the in situ generation of a neutral-enriched deposition medium that is conducive to the formation of thin film materials having a low intrinsic defect concentration at any speed. In one embodiment, the deposition medium is created by forming a plasma from an energy transferring gas; combining the plasma with a precursor gas to form a set of activated species that include ions, ion-radicals, and neutrals; and selectively excluding the species that promote the formation of defects to form the deposition medium. In another embodiment, the deposition medium is created by mixing an energy transferring gas and a precursor gas, forming a plasma from the mixture to form a set of activated species, and selectively excluding the species that promote the formation of defects. The apparatus has a control for the entire manufacturing process that includes a diagnostic element and a feedback control element to permit process programming to achieve and maintain the optimal distribution of one or more preferred species throughout the deposition process.

### RELATED APPLICATION INFORMATION

This application is a continuation-in-part of U.S. patent application Ser. No. 11/546,619, entitled “High rate, continuous deposition of high quality amorphous, nanocrystalline, microcrystalline or polycrystalline materials” and filed on Oct. 12, 2006, the disclosure of which is incorporated by reference in its entirety herein.

### FIELD OF INVENTION

The instant invention relates generally to an apparatus and method for the high rate deposition of high quality amorphous, nanocrystalline, microcrystalline or polycrystalline materials. More specifically, the instant invention provides an apparatus and method for scientifically tailoring the distribution of deposition intermediates to preferentially increase the concentration of intermediates conducive to the formation of photovoltaic materials that have a low concentration of intrinsic defects in the as-deposited state. Most specifically, the instant invention provides an apparatus and method for selectively producing, monitoring, and consistently maintaining the distribution of deposition intermediates that optimizes the quality of as-deposited photovoltaic materials so as to achieve a decoupling of deposition rate and material quality.

Suppression of intrinsic defects decreases the concentration of midgap states that capture charge carriers and detract from solar conversion efficiency. The need to dedicate time and resources to the passivation of defects during processing is thereby minimized. As a result, the instant invention enables the continuous deposition of photovoltaic materials at heretofore unachievable speeds. Feedback controls are implemented to sense and preserve the optimal distribution of deposition intermediates through continuous reconfiguration of deposition conditions to insure the uniformity of the as-deposited material over large area substrates. The combination of high speed deposition, low defect density, and uniform large area coverage provided by the instant invention enables society, for the first time, to realize the benefits of solar energy at a cost that is competitive with fossil fuels.

### BACKGROUND OF THE INVENTION

The recent escalation of the cost of energy derived from fossil fuels has stimulated strong interest in the development of alternative energy sources. Significant investments in areas such as batteries, fuel cells, hydrogen production and storage, biomass, wind power, algae, and solar energy seek to develop new ways of creating and storing energy in an economically competitive fashion. The ultimate objective is to minimize society's reliance on increasingly scarce fossil fuels and to do so in a particularly environmentally friendly way that minimizes or eliminates greenhouse gas production.

The field of solar energy is currently dominated by solar cells constructed of crystalline silicon. Crystalline silicon, however, has a number of disadvantages as a solar energy material. First, preparation of crystalline silicon is normally accomplished through a seed-assisted Czochralski method. The method entails a high temperature melting process along with controlled cooling at near-equilibrium conditions and refining to produce a boule of crystalline silicon. Although high purity crystalline silicon can be achieved and the method is amenable to n- and p-type doping, the method is inherently slow and energy intensive.

Second, as an indirect gap material, crystalline silicon has a low absorption efficiency. Thick layers of crystalline silicon are needed to obtain enough absorption of incident sunlight to achieve reasonable solar conversion efficiencies. The thick layers add to the cost of crystalline silicon solar panels and lead to a significant increase in weight. The increased weight necessitates bulky installation mounts and precludes the use of crystalline silicon in a number of applications.

Amorphous silicon (and hydrogenated or fluorinated forms thereof) is an attractive alternative to crystalline silicon. Amorphous silicon is a direct gap material with a high absorption efficiency. As a result, lightweight and efficient solar cells based on thin layers of amorphous silicon or related materials are possible. The instant inventor, Stanford R. Ovshinsky, is the seminal figure in modern thin film semiconductor technology. Early on, he recognized the advantages of amorphous silicon (as well as amorphous germanium, amorphous alloys of silicon and germanium as well as doped, hydrogenated and fluorinated versions thereof) as a solar cell material and pioneered the continuous manufacturing techniques needed to produce thin film, flexible solar panels based on amorphous, nanocrystalline, microcrystalline, polycrystalline or composite semiconductors. Representative discoveries of Stanford R. Ovshinsky in the field of amorphous semiconductors and photovoltaic materials are presented in U.S. Pat. No. 4,400,409 (describing a continuous manufacturing process for making thin film photovoltaic films and devices); U.S. Pat. No. 4,410,588 (describing an apparatus for the continuous manufacturing of thin film photovoltaic solar cells); U.S. Pat. No. 4,438,723 (describing an apparatus having multiple deposition chambers for the continuous manufacturing of multilayer photovoltaic devices); U.S. Pat. No.4,217,374 (describing suitability of amorphous silicon and related materials as the active material in several semiconducting devices); U.S. Pat. No. 4,226,898 (demonstration of solar cells having multiple layers, including n- and p-doped); U.S. Pat. No. 5,103,284 (deposition of nanocrystalline silicon); and 5,324,553 (microwave deposition of thin film photovoltaic materials) as well as in articles entitled “The material basis of efficiency and stability in amorphous photovoltaics” (Solar Energy Materials and Solar Cells, vol. 32, p. 443-449 (1994); and “Amorphous and disordered materials—The basis of new industries” (Materials Research Society Symposium Proceedings, vol. 554, p. 399-412 (1999).

Current efforts in photovoltaic material manufacturing are directed at increasing the deposition rate. Higher deposition rates lower the cost of thin film solar cells and lead to a decrease in the unit cost of electricity obtained from solar energy. As the deposition rate increases, thin film photovoltaic materials become increasingly competitive with fossil fuels as a source of energy. Presently, PECVD (plasma-enhanced chemical vapor deposition) has proven to be the most cost-effective method for the commercial scale manufacturing of amorphous silicon and related solar energy materials. Current PECVD processes provide uniform coverage of large-area substrates with device quality photovoltaic material at a deposition rate of ˜3 Å/s.

In order to leap beyond a deposition rate of ˜3 Å/s, it is necessary to overcome basic limitations associated with current PECVD techniques. One of the problems with photovoltaic materials prepared by conventional PECVD techniques is the presence of a high concentration of intrinsic defects in the as-deposited state. The intrinsic defects are structural defects (e.g. dangling bonds, strained bonds, unpassivated surface states, non-tetrahedral bonding distortions, coordinatively unsaturated silicon or germanium) that create electronic states within the bandgap of the photovoltaic material. The midgap states detract from the solar conversion efficiency of photovoltaic materials because they act as nonradiative recombination centers that deplete the concentration of free carriers generated by absorbed sunlight. Instead of being available for external current, the energy available from many of the photoexcited free carriers is dissipated thermally. The external current delivered by a photovoltaic material upon absorption of a given amount of sunlight is reduced accordingly.

The intrinsic defects are also believed to contribute to a degradation of solar cell performance of silicon-based photovoltaic materials through the Staebler-Wronski effect. The Staebler-Wronski effect is a photo-induced degradation of amorphous silicon and related materials (e.g. hydrogenated, fluorinated or doped forms thereof) that causes up to a ˜25% decrease in the solar efficiency upon exposure to light. Although the origin of the Staebler-Wronski effect has not been definitively established, it is believed that a contributing factor is the creation of new defects that provide additional midgap states due to a transfer of energy from photocarriers excited by incident light to intrinsic structural defects.

A common strategy for reducing the concentration of intrinsic defects in amorphous silicon, related materials, and other photovoltaic materials prepared by conventional PECVD is to include a defect compensating agent in the plasma. Inclusion of fluorine or excess hydrogen in the plasma, for example, leads to a marked improvement in the quality of the material and the ability to make nanocrystalline phases. The compensating agents passivate defects, saturate bonds, relieve bond strain and remove non-tetrahedral structural distortions that occur in as-deposited material. As a result, the concentration of midgap band states is reduced and higher solar conversion efficiency is achieved.

Recognizing that the use of excess H₂ leads to poor gas utilization and the formation of polysilane powders, Ovshinsky has advocated the use of fluorine. In particular, Ovshinsky has shown that the inclusion of fluorine provides more regular bonding, leads to fewer defects, and enables deposition of nanocrystalline materials. (See U.S. Pat. No. 5,103,284 (formation of nanocrystalline silicon from SiH₄ and SiF₄); U.S. Pat. No. 4,605,941 (showing substantial reduction in defect states in amorphous silicon prepared in presence of fluorine); and U.S. Pat. No. 4,839,312 (presents several fluorine-based precursors for the deposition of amorphous and nanocrystalline silicon)).

Although defect compensating agents improve the performance of photovoltaic materials, it has been necessary to slow the deposition process to realize their benefits. Compensation or repair of intrinsic defects requires a sufficient time of contact of the compensating agent with as-deposited photovoltaic material. It is also necessary for the compensating agents to act throughout the deposition process. When an initial layer of photovoltaic material is deposited, it includes a certain concentration and distribution of intrinsic defects. Since the defect compensation process occurs preferentially at the surface, it is necessary to expose the as-deposited material to the compensating agent before an additional thickness of photovoltaic material is deposited. If the deposition continues before the defects are compensated, the defects become incorporated within the bulk of the material and are increasingly difficult to remove by subsequent exposure to a defect compensating agent. As a result, the best quality photovoltaic material is prepared at deposition rates slow enough to insure that the defect compensating agents fully interact with the as-deposited material.

A need exists in the art for a method for preparing photovoltaic materials (including amorphous, nanocrystalline, microcrystalline, and polycrystalline forms of silicon, germanium, and alloys of either) at high deposition rates without sacrificing the quality of the material. The low deposition rates needed to achieve high quality photovoltaic materials through conventional PECVD limits the economic competiveness of conventional PECVD and motivates a search for new deposition processes.

### SUMMARY OF THE INVENTION

This invention provides a method and apparatus for the high rate deposition of amorphous, nanocrystalline, microcrystalline, and polycrystalline semiconductors and semiconductor alloys. Materials that can be prepared according to the instant invention include the amorphous, nanocrystalline, microcrystalline, and polycrystalline forms of silicon, alloys of silicon, germanium, alloys of germanium, hydrogenated and fluorinated materials that include silicon or germanium, and combinations thereof, The target materials are particularly suitable for photovoltaic applications. The invention involves plasma deposition and focuses on controlling the growth environment of the as-deposited film to limit the development of intrinsic defects. The need for compensating agents or other reparative processing steps is thereby minimized or eliminated and high quality photovoltaic materials can be produced at deposition rates of ˜300 Å/s and higher.

A conventional plasma is a chaotic state of matter that includes a distribution of ions, ion-radicals and neutral radicals. The instant method recognizes that within the distribution of species in a conventional plasma, only selected species are effective in the formation of amorphous semiconductors with low defect densities and that many species in a plasma are ineffective and detrimental because they promote the formation of defects. One embodiment of the method includes a separation of the effective plasma species from the ineffective plasma species, delivery of the effective plasma species to a substrate, and deposition of an amorphous semiconductor or other photovoltaic material from the effective plasma species. The defect concentration in the as-deposited material is reduced by neutralizing or excluding the ineffective plasma species from interacting with the material during deposition. Separation of ineffective plasma species from effective plasma species produces a deposition medium that may or may not be a plasma. In one embodiment, the effective plasma species include primarily neutral radicals and separation of the ineffective plasma species produces a non-plasma deposition medium that includes primarily neutral radicals.

The method further includes sensing the presence of the effective and ineffective plasma species in the deposition apparatus or chamber and adjustment of the plasma generation and separation schemes or deposition process to maximize the ratio of effective species to ineffective species. The deposition process can be programmed through a feedback control protocol that is responsive to deviations of the distribution of plasma species from the desired condition. In one embodiment, the distribution of plasma species is sensed with a mass spectrometer. Sensing of the plasma may occur in the vicinity of plasma generation, in the region following separation of the plasma into effective and ineffective species, and/or in the growth front adjacent to the deposition surface. Sensing may also occur at the surface of or within the interior of the as-deposited material. In one embodiment, an optical probe of the presence of defects in the as-deposited material is employed. Raman spectroscopy, for example, can be utilized in real time to detect the presence of dihydride defects. Ellipsometry may also be employed to monitor optical constants of the as-deposited material. In a further embodiment, luminescence spectroscopy is used to detect the presence of midgap defects.

The apparatus includes a plasma activation source and electrostatic means for separating the effective plasma or deposition species from the ineffective plasma or deposition species. In one embodiment, the separation means is a mesh with a voltage bias that can be adjusted to selectively reject charged plasma species (ions and ion-radicals) while permitting neutral species (neutral radicals, atoms, atomic clusters or molecules) to pass and enter the deposition zone. The bias can be a constant bias, variable bias, or alternating bias. The bias can be applied to a single mesh or to a plurality of meshes. In one embodiment, a graded bias is distributed across a series of meshes.

In one embodiment, the plasma activation source receives an energy transferring gas, creates a plasma and delivers the plasma to a precursor gas to form a pre-deposition medium. The pre-deposition medium is transferred to the separation means to cull ineffective species to produce a deposition medium that is directed to a substrate for film deposition. In another embodiment, the plasma generation source creates a plasma from a mixture of the energy transferring gas and the precursor gas. This plasma constitutes a pre-deposition medium that is directed to the separation means to produce a deposition medium enriched in effective species for transport to a substrate and film growth.

The apparatus further includes a sensing unit to detect the state of the initial plasma, pre-deposition medium, and deposition medium. The sensing unit assesses the distribution of species at one or more points in the apparatus and delivers a process signal that reflects the distribution to a feedback controller. The feedback controller compares the process signal to a target signal that has been predetermined to correlate with the optimum distribution of species. The feedback controller responds to deviations from the target signal by adjusting the flow rate or composition of the energy transferring gas, the flow rate or composition of the precursor gas, the ratio of the amount of energy transferring gas relative to the amount of precursor gas, the pressure of the deposition environment, the substrate temperature, and/or the bias on one or more meshes. The sensing unit may also include an optical or electrical probe to assess the quality of the as-deposited material. An object of the invention is to permit in situ monitoring and optimization of deposition conditions as well as continuous removal of intermediate species that promote the formation of defects in the as-deposited material.

By permitting the formation of as-deposited material with a low concentration of defects, the instant apparatus avoids the need to dedicate process time to the removal or passivation of intrinsic defects. Deposition rate and quality of the deposited material become decoupled. As a result, the deposition rate can be increased substantially without compromising material quality and the unit cost of solar energy is reduced to a level that becomes competitive with fossil fuels. Implementation of the instant invention allows mankind to reduce its dependence on fossil fuels and democratizes energy by enabling all countries, regardless of natural resources, to become self sufficient in energy. The invention provides a fundamental contribution to plasma chemistry and physics and exploits the advance to achieve a process system that can produce not just megawatts of photovoltaic material, but rather gigawatts in a machine that is the length of a football field that is capable of producing miles and miles of photovoltaic material in a single run.

The instant invention allows for a tremendous increase in the throughput and film formation rate in continuous web deposition processes. With the invention, the web speed can be increased without sacrificing the quality of the thin film layers produced and without introducing defects that diminish photovoltaic efficiency. The instant invention enables for the first time a GW manufacturing capacity. The technology can be applied to single layer devices as well as multilayer devices, including the triple junction solar cell, that provide bandgap tuning and more efficient collection of the solar spectrum.

The impact of the invention extends beyond solar energy to the entire energy cycle. By achieving a cost-superior method of producing electrical energy, the instant invention unlocks the hydrogen economy by making it possible to obtain hydrogen from water, including brackish water, at costs that obviate the need for fossil fuels. Hydrogen is the holy grail of energy supplies because it is the most abundant element in the universe and provides an inexhaustible fuel source to meet the increasing energy demands of the world. The sources of hydrogen are also geographically well-distributed around the world and are accessible to most of the world's population without the need to import. Since the photovoltaic materials produced by the instant invention are thin film, flexible, light weight and can be produced by the mile, the harvesting of hydrogen from lakes, ponds, and other sources of water becomes a simple matter of spreading the photovoltaic material prepared by the instant apparatus across the surface of water and collecting the hydrogen as it is produced from the sunlight. It is important to note that the photovoltaic material itself can be spread across land, with electrodes extending to a source of water to effect hydrogen production. Triple junction solar cells are especially well-adapted for water splitting applications. Because of the extremely low cost of splitting water with solar materials prepared from the instant invention, it also becomes economically viable to purify brackish or contaminated water by splitting it and recombining the hydrogen and oxygen produced to form pure water.

Displacement of fossil fuels as the primary energy source of the world has enormous consequences for the quality of life on Earth. Fossil fuels are highly polluting, contribute to global warming, and endanger the stability of the earth's ecosystem. The use of solar energy and hydrogen as fuel sources will eliminate much of the world's pollution. Hydrogen is the ultimate clean fuel source because combustion of hydrogen produces only water as a byproduct. The production of greenhouse gases that are so harmful to the Earth's environment is avoided. The sun fuses hydrogen for its energy and this fusion provides the photons utilized in our photovoltaic material. Up until now, a low cost method of creating electrical energy from the solar spectrum has been lacking. This invention fulfills this important need and enables the completion of an energy cycle that begins with the sun.

Other problems associated with the use of fossil fuels are also avoided with the instant invention. As worldwide use of fossil fuels has increased, the world has appreciated that fossil fuels are a truly finite resource and concern has grown that fossil fuels will become fully depleted in the foreseeable future. Scarcity raises the possibility that escalating costs could destabilize economies as well as increase the likelihood that nations will go to war over the remaining reserves.

The problems of pollution, scarcity, and conflict associated with fossil fuels are eliminated by the instant invention. The revolutionary breakthrough presented in this invention is a total energy solution that includes a machine, creative manipulation of a plasma, and high deposition rates. The machine may also include the pore cathode, disclosed in pending U.S. patent application Ser. Nos. 11/447,363 and 10/043,010, the disclosures of which are incorporated by reference herein. The pore cathode assures uniformity in the thickness and activity of the deposited photovoltaic material over any width of web by utilizing pores of a size and spacing that are particularly suited to the optimal formation of a plasma.

Gigawatt production rates become achievable for the first time with the instant invention in a single run. As a result, the capital costs per watt of electricity plummet and the product cost becomes low enough to effectively compete with fossil fuels. The overall result of the instant invention will be the development of new industries that include high-valued jobs that stimulate the economy and promote the educational system. The instant inventor projects that the invention will have consequences that are as far-reaching worldwide as the advent of electricity was in prior centuries. It is the sincere hope of the instant inventor that this breakthrough will not only make energy available in a secure manner in local areas, but also free mankind from the paradigm that energy can only be found in areas of the world susceptible to wars. Advancement of human civilization to a higher level is the ultimate goal.

### BRIEF DESCRIPTION OF THE DRAWINGS

FIG. 1 is a schematic depiction of several species present in a conventional silane plasma.

FIG. 2 is a schematic depiction of an apparatus for the deposition of amorphous semiconductors that includes a charged mesh for separating charged plasma species from uncharged plasma species.

FIG. 3 is a schematic depiction of a flow process that provides a neutral-enriched deposition medium for deposition of a thin film material on a substrate.

FIG. 4 is a schematic depiction of a flow process that provides a neutral-enriched deposition medium for deposition of a thin film material on a substrate.

FIG. 5 is a schematic depiction of a flow process that provides a neutral-enriched deposition medium for deposition of a thin film material on a substrate.

FIG. 6 is a schematic depiction of a continuous web embodiment according to the principles of the instant invention.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein, are also within the scope of this invention. Accordingly, the scope of the invention is defined only by reference to the appended claims.

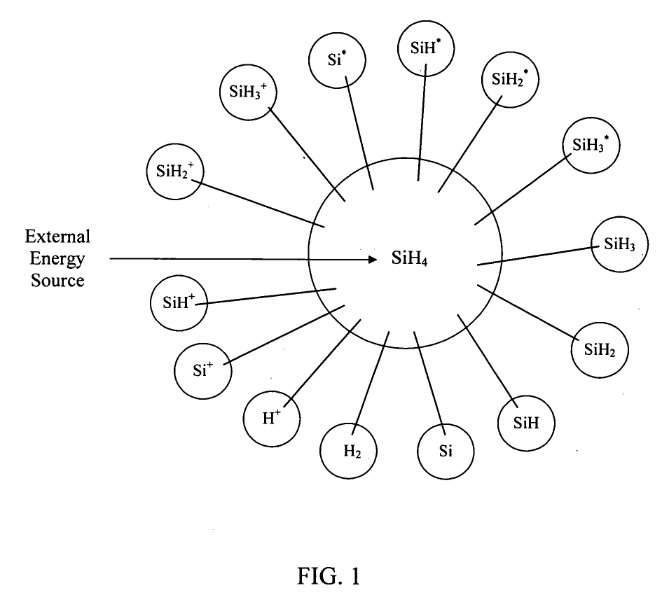

This invention provides a high deposition rate apparatus for the formation of photovoltaic materials that have a low concentration of intrinsic defects in the as-deposited state in a plasma deposition process. The invention recognizes that a conventional plasma includes many species that are detrimental to the formation of high quality photovoltaic materials. FIG. 1 depicts the distribution of the most common species in a silane (SiH₄) plasma, which is used in the formation of amorphous silicon, modified forms of amorphous silicon, nanocrystalline silicon, microcrystalline silicon, and polycrystalline silicon. The plasma includes a variety of ions, radicals and molecular species. Neutral radicals include SiH₃, SiH₂, SiH, Si, and H. The species may be in a ground state or an excited state (designated by an asterisk (e.g. SiH* is a radical in an excited state)). In a conventional silane plasma deposition process, the relative proportions of the different plasma species depend on deposition parameters such as the electron temperature, electron density, and residence time. In general, however, a conventional plasma includes species that are conducive to the formation of high quality as-deposited material as well as species that are detrimental to the formation of high quality as-deposited material.

One of many objectives of the instant invention is to optimize the distribution of species present in the growth zone of photovoltaic materials. The invention provides an apparatus and method for preferentially selecting the species in a plasma or other ionized gas medium most conducive to the formation of high quality photovoltaic materials and could be very useful for other industries as well. In one embodiment, the preferred species for photovoltaic material deposition are neutral radicals and the instant invention provides a method and apparatus for removing ions and ion-radicals from a plasma or other ionized gas medium to produce a deposition medium that is enriched in neutral radicals. While not wishing to be bound by theory, most ions and ion-radicals are believed to be detrimental to the formation of amorphous silicon and other photovoltaic materials. By virtue of their charge, ions and ion-radicals tend to undergo high energy collisions with a deposited layer of a photovoltaic material. The high energy collisions can create defects in a photovoltaic material in its as-deposited state by breaking bonds (such as Si—H bonds), ejecting atoms or clusters, or inducing non-tetrahedral structural distortions. Ions and ion-radicals also have high sticking coefficients and remain on the surface of as-deposited material at the point of impact, even if the bonding configuration at the point of impact is structurally or coordinatively non-optimal. The high sticking coefficient also means that ions and ion-radicals have low surface mobility and do not participate in thermally-driven surface reconstruction processes that optimize preferred bonding configurations. Neutral radicals, in contrast, impinge the surface of as-deposited material with lower energy, cause less damage, and create fewer defects. The sticking coefficient of neutrals is also lower than that of ions or ion-radicals, which means that neutrals that initially incorporate in a non-optimal bonding configuration have a lower activation to surface mobility and are more likely to migrate on the surface to encounter an optimal, energetically preferred bonding site during processing. The concentration of intrinsic defects is lowered accordingly.

Photovoltaic materials that can be prepared according to the method and apparatus of the instant invention include amorphous silicon; hydrogenated amorphous silicon; fluorinated amorphous silicon; amorphous germanium; hydrogenated amorphous germanium; fluorinated amorphous germanium; amorphous silicon-germanium alloys as well as hydrogenated and fluorinated forms thereof, nanocrystalline, microcrystalline, and polycrystalline forms of silicon, germanium, silicon-germanium alloys as well as hydrogenated and fluorinated forms thereof; composite materials that combine one or more of the amorphous, nanocrystalline, microcrystalline or polycrystalline forms of the foregoing; and n-type or p-type variations of the foregoing achieved by doping with, for example, column III (e.g. B, Al, Ga, In) or column V (e.g. P, As, Sb) elements.

In co-pending U.S. patent application Ser. No. 11/546,619 (“'619 application”), the disclosure of which is incorporated by reference in its entirety herein, the instant inventor described an apparatus and method for generating a plasma and separating charged plasma species from uncharged plasma species. One objective of the '619 application was to provide an apparatus and method of depositing a high quality amorphous semiconductor by establishing a growth environment that was enriched with neutral species that were selectively extracted from the initial plasma. By removing deleterious charged species from the plasma and concentrating the neutral species in the vicinity of the deposition surface, the method and apparatus of the '619 application permits growth of amorphous silicon with a low intrinsic defect concentration at heretofore unachievable deposition rates.

The method of the '619 application included the following general steps: (1) provision of an energy transferring gas (e.g. one or more of He, Ne, Ar, Kr, Xe, H₂) at transonic velocity to a plasma activation region within a deposition apparatus or chamber; (2) generation of a supply of activated species (which include ions, ion-radicals, and neutral radicals) by creating a plasma from the energy transferring gas in the plasma activation region; (3) separation of charged activated species from neutral activated species to form a pre-deposition medium that is enriched in neutral species relative to the initial plasma; (4) delivery of the pre-deposition medium to a collision region by providing a pressure differential between the activation region and the collision region to direct the neutral-enriched pre-deposition medium to the collision region and to maintain adequate velocity of motion to provide the neutral-enriched pre-deposition medium to the collision zone without significant decay or transformation; (5) introduction of a feedstock gas including a deposition precursor into the collision region to physically and chemically interact with the neutral-enriched pre-deposition medium to form a deposition medium that includes a high concentration of deposition species that are conducive to the formation of low defect material; and (6) high rate deposition of a high quality thin film material from the deposition medium onto a substrate.

In one embodiment, the energy transferring gas may be supplied through the pores of the pore electrode invented by S. R. Ovshinsky in U.S. Patent Application Publication No. 20040250763. The pore electrode may be used to initiate a plasma from the energy transferring gas and is particularly suited for uniform deposition over large area stationary or continuous web substrates. The pore electrode further permits control of the species created during plasma formation. The pore electrode produces a plasma from a gas flowing in the interior thereof and exiting holes thereof in the presence of an electric field. By controlling the size, shape, and spacing of the holes, the species capable of exiting the pore electrode can be controlled. The holes of the pore electrode can be designed to pass selected plasma species, while rejecting or neutralizing other plasma species. Pore dimensions can extend to the quantum regime to provide great selectivity over the composition of the plasma. A more uniform and monolithic plasma can be formed from which higher quality materials can be deposited.

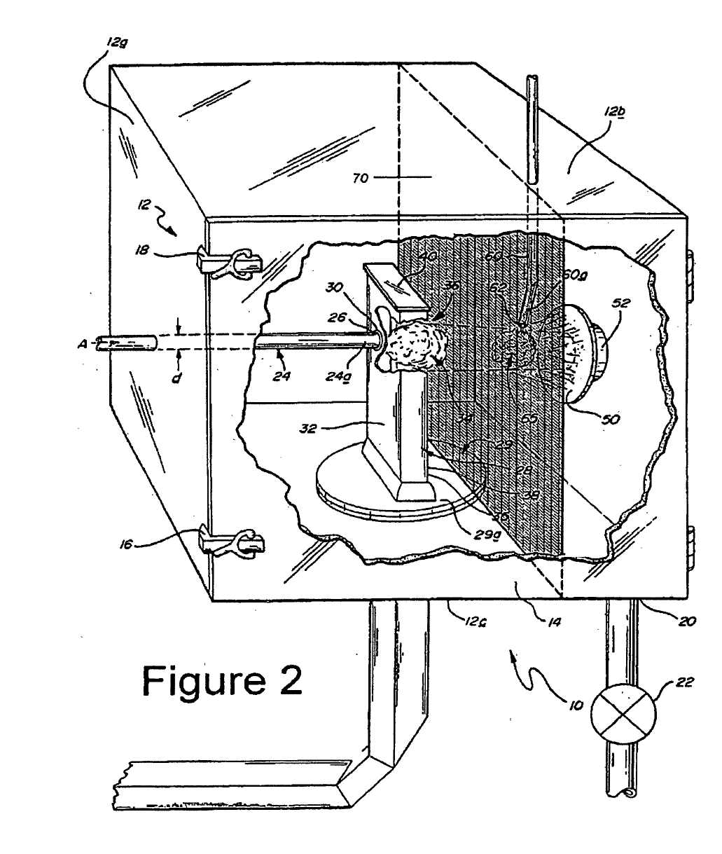

A schematic depiction of the apparatus of the '619 application is shown in FIG. 2. FIG. 2 depicts a perspective view, partially cut-away, of a reaction apparatus 10 that is adapted to generate a plume of activated species from an energy transferring gas introduced into the interior thereof. The apparatus 10 includes an evacuable enclosure 12 with a pivotally mounted front face 14 which functions as a door for loading and removing substrates from the interior of the enclosure. The inner periphery of the door 14 is equipped with one or more vacuum seal rings (not shown) and one or more latches, such as 16 and 18, that are adapted to compress the seal rings for assuring airtight closure of the enclosure 12. The evacuated enclosure 12 further includes a pump-out port 20 in the bottom wall 12c thereof adapted for connection to a vacuum pump 22 which is employed to: (1) exhaust depleted reaction products and (2) to maintain the interior of enclosure 12 at an appropriate sub-atmospheric background pressure. As will be explained in greater detail hereinbelow, the background pressure is carefully selected to initiate and sustain the high rate deposition process occurring within the interior of the enclosure.

The apparatus 10 further includes at least a first elongated conduit 24 of diameter d, where d is preferably between about 0.5 to 3.0 cm, that extends through a side wall 12a into the interior of evacuated enclosure 12. First conduit 24 includes a distal end portion 24a having an aperture 26 formed therein. First conduit 24 and aperture 26 are adapted to, respectively, transmit and introduce an energy transferring gas from a source (not shown) into the interior of evacuated enclosure 12, preferably to a point immediately adjacent apparatus (e.g. plasma generation means) adapted to provide or create activated species from the energy transferring gas. In the embodiment depicted in FIG. 2, the activation apparatus is a radiant microwave applicator 28, discussed in greater detail hereinbelow.

In one embodiment, first conduit 24 is adapted to introduce an energy transferring gas selected from the group consisting essentially of hydrogen (H₂), methane (CH₄), neon (Ne), helium (He), argon (Ar), krypton (Kr) or combinations thereof. Optionally, the foregoing energy transferring gases may also include one or more diluent, treatment (e.g. hydrogenation or fluorination), or dopant (including n-type or p-type) gases, including, but not limited to, O₂, NH₃, N₂, NH₃, PH₃, PH₅, SF₆, BF₃, B₂H₆, BH₃ and combinations thereof.

Regardless of the composition of the energy transferring gas employed, aperture 26 formed at distal end 24a of first conduit 24 must be capable of delivering the energy transferring gas at a preferred flow rate. The flow rate is selected to provide a sufficient pressure of the energy transferring gas at aperture 26 for initiating the plasma activation of the energy transferring gas at a power-pressure-aperture size regime which is at or near the minimum of the modified Paschen curve.

First conduit 24 may further include means for constricting the flow path of the energy transferring gas to create a “choke-condition” in first conduit 24 adjacent to aperture 26 so as to provide a localized high pressure of the energy transferring gas. As used herein, the term “choke condition” refers to the condition that occurs when the speed of the energy transferring gas passing through aperture 26 of first conduit 24 reaches transonic speed. The choke condition generally is that condition that occurs in compressible gas or fluid flow when, for a conduit of a uniform size, the speed of the gas passing through said conduit reaches transonic velocity. It is at the choke condition that a rise in the mass flow rate of the energy transferring gas results in an increase in pressure rather than velocity. Operation in choke mode permits control over the pressure of the energy transferring gas and provides the degree of freedom in operating conditions needed to establish a condition at or near the minimum of the Paschen curve. The localized high pressure established at aperture 26 creates a zone of sufficient pressure of the energy transferring gas as it exits aperture 26 to enable initiation of a plasma. In an alternative embodiment, the pressure at or near aperture 26 may be controlled by employing a solenoid valve within first conduit 24, where the solenoid valve may be selectively constricted or relaxed to regulate the flow rate and pressure of the energy transferring gas as it passes through aperture 26.

Note that the activated species of the energy transferring gas form a plume 34 of pressure isobars adjacent to aperture 26 of first conduit 24. Plume 34 defines an activation region in which conditions permit plasma initiation and formation of activated species that include ions, ion-radicals and neutral radicals in conventional proportions. The boundaries of the plume of activated species 34 are governed by the pressure differential that exists between the gas flowing through the interior of first conduit 24 adjacent to aperture 26 and the background pressure of enclosure 12. As should be apparent, material that is sputtered or ablated from the surface of first conduit 24 would degrade the quality of the activated species in plume 34 by providing undesirable impurities or other deleterious species that could be delivered to the deposition surface and incorporated into the as-deposited amorphous semiconductor. Thus, a protective overcoat is preferably fabricated over the surface of first conduit 24. The protective overcoat is preferably formed from a material that is resistant to a high temperature plasma environment; or alternatively, from a material that would be relatively benign when incorporated into the as-deposited film. In a preferred embodiment, graphite is employed as the material from which the protective overcoat is fabricated. Graphite is not only highly resistant to high temperature sputtering processes, but also substantially electrically benign to the desired characteristics of the as-deposited semiconductor film.

Deposition apparatus 10 further includes microwave applicator 28 that is adapted to deliver electromagnetic energy at a microwave frequency (e.g. 2.45 GHz) to the energy transferring gas flowing through first conduit 24. While applicator 28 is depicted as a radiant microwave applicator in FIG. 2, the applicator may be selected to deliver any type of energy, including DC energy, microwave energy, radiofrequency (rf) energy, low frequency AC energy, or other electromagnetic energy (e.g. in the form of a high intensity pulsed laser). A plasma in accordance with the instant invention may be formed from electromagnetic energy over the frequency range from 0 Hz to 5 GHz. Since microwave energy can effectively provide a large-volume plasma that contains a high density of activated species, applicator 28 is preferably formed as a microwave applicator. Preferably, applicator 28 is a radiant microwave applicator (as opposed to slow-wave applicator) adapted to transmit at least 1.0 kilowatt of microwave power and preferably 5 kilowatts or more of microwave power at a frequency of 2.45 GHz.

As indicated in FIG. 2, applicator 28 is an elongated, hollow, generally rectangular waveguide structure adapted to transmit microwave energy from a magnetron (not shown) to the energy transferring gas introduced into enclosure 12 from first conduit 24. Applicator 28 may be formed from a material such as nickel or nickel-plated copper. Applicator 28 enters enclosure 12 through a microwave transmissive window 29, which window is vacuum sealed to a bottom face 12c of enclosure 12. This type of vacuum sealed window 29 is fully disclosed and well known in the art. Applicator 28 is seated upon the upper, interior plate 29a of window 29.

In order to couple the microwave energy to the energy transferring gas, first conduit 24 extends through an aperture 30 formed in the side face 32 of applicator 28 to deliver the energy transferring gas. Aperture 30 is adapted to direct first conduit 24 and the energy transferring gas carried therewithin to plume activation region 34 formed adjacent to aperture 26 of first conduit 24 so that the plume of activated species extends from the interior of applicator 28.

Applicator 28 further includes cut-away section 36 formed in the face 35 thereof opposite the face 32 in which the aperture 30 is formed. Cut-away section 36 has a diameter larger than the diameter of the aperture 30 and preferably at least about 2 inches so as to provide for the expansion and movement pressure isobars of the plume 34 of activated species through and from applicator 28 while avoiding interaction of the activated species with the walls of applicator 28 to prevent both incorporation of the material of construction of applicator 28 into the plume 34 as it exits applicator 28 and deterioration of applicator 28. It should therefore be understood that the applicator cut-away section 36 is adapted to provide a means of directed escape for the activated species of the energy transferring gas from within applicator 28. Applicator 28 further includes a closed end plate 40 to prevent the escape of unused microwave energy into the interior of evacuated enclosure 12. Considerations relevant to establishing the size of cut-away section 36 include: (1) recognition that the smaller the opening is made in face 35, the greater the amount of material etched from face 35, but the better the microwave energy is confined within applicator 28 and prevented from leaking into enclosure 12, while (2) the larger the opening is made in face 35, the lesser the amount of material etched from face 35, but the more the microwave energy leaks into enclosure 12. Cutaway section 36 may further include a microwave absorptive or reflective screen or other means adapted to prevent the microwave energy from escaping applicator 28 and entering enclosure 12. This becomes particularly significant as the pressure differential between the background pressure and the pressure of the energy transferring gas in first conduit 24 is reduced to approach the aforementioned factor of at least 5.

Deposition apparatus 10 further includes at least one remotely located, generally planar substrate 50 operatively disposed within enclosure 12 to provide a surface for the deposition of a thin film material. Planar substrate 50 is spaced at a distance from activation region 34 sufficient to prevent the depositing thin film material from direct exposure to the electrons present in activation region 34. Electrons in activation region 34 have high energy and inflict severe damage on the thin film material as it deposits.

Deposition apparatus 10 further includes at least one separation element, such as an electrically-biased screen or mesh 70, for selectively removing deleterious species from plume 34 exiting cut-away section 36 of applicator 28 to form a pre-deposition medium that is directed to collision region 65. One or more screens or meshes are disposed between the energy transferring gas activation region 34 and collision region 65. Screen 70 is electrically biased. The bias may be any of 1) a positive bias to repel positively-charged ions or ion-radicals present in plume 34 as it passes therethrough, 2) a positive bias to attract and neutralize negatively-charged ions or ion-radicals, 3) a negative bias to repel negatively-charged ions or ion-radicals present in plume 34, 4) a negative bias to attract and neutralize positively-charged ionic species, or 5) a plurality of screens with opposite biases. By rejecting or neutralizing ions and ion-radicals while passing neutral species within plume 34, electrically-biased screen 70 creates a pre-deposition medium that is enriched in neutral species. Electrically-biased screen 70 also acts (along with the positive ions) to attract the electrons within the plume and insure that they do not reach collision region 65.

Screen 70 is spaced far enough from plasma activation region 34 to insure that the screen is not etched or otherwise destroyed by the plasma. Screen 70 is made of a material that is resistant to the effects of the plasma. Preferred materials include graphite, tungsten, nickel and nickel-plated materials. Screen 70 is also spacedly disposed from the collision region 65 such that any stray electrons that pass through the screen do not impinge upon the collision region. Interaction of free electrons with the pre-deposition medium exiting screen 70 or precursor gases leads to the formation of deleterious ionic species in the deposition medium and promotes the formation of defects in the as-deposited material formed on substrate 50. Apparatus 10 may further include a plurality of meshes or screens, each one providing an additional degree of separation (fractionation) of the charged species from the neutral species within plume 34 of activated species.

Apparatus 10 may further optionally include means 52 adapted to heat and or apply an electrical or magnetic bias to substrate 50. It is to be understood, however, that the use of heat or a bias is not required to practice the invention disclosed herein. In a preferred embodiment, substrate 50 is operatively disposed so as to be substantially aligned with first conduit 24 so that a flux of the activated species generated in the activation region 34 can be directed thereat for deposition thereupon.

Deposition apparatus 10 is also equipped with means for introducing a precursor gas into enclosure 12. In the embodiment shown in FIG. 2, deposition apparatus 10 is equipped with a second elongated, hollow conduit 60 having at least one aperture 62 formed at the distal end 60a thereof. Aperture 60a of second conduit 60 extends through top wall 12b of enclosure 12 into the interior thereof so that aperture 62 terminates in close proximity to substrate 50. Second conduit 60 is adapted to deliver a flow of a precursor deposition gas from a source (not shown) into a collision region 65 which is created adjacent to substrate 50. Collision region 65 is disposed between substrate 50 and screen 70 and generally represents the region in which the neutral-enriched pre-deposition medium exiting screen 70 interacts with the precursor gases exiting aperture 62 of second conduit 60 to form a deposition medium from which a thin film is formed on substrate 50.

The precursor deposition gas of the '619 application and the instant application is typically a silicon-containing gas, a germanium-containing gas, a carbon-containing gas, a dopant-containing gas (n- or p-type) and combinations thereof. Representative precursor deposition gases include, but are not limited to, SiH₄, Si₂H₆, SiF₄, GeH₄, Ge₂H₆, GeF₄, CH₄, C₂H₆, BH₃, B₂H₆, PH₃, and combinations thereof. The precursor gas may also be an alkyl-substituted or halide-substituted form of the foregoing. For example, alkyl-substituted silane and/or alkyl-substituted germane are suitable precursor gases of this invention. Alkyl substitution may occur in one position or multiple positions of the precursor gas. Substitutional alkyl groups include methyl, ethyl, propyl, and butyl groups. The precursor deposition gas may be transported via a carrier gas such as H₂ or a noble gas. The flow rate of the precursor gas is typically at least about 10 sccm and preferably between about 10 and 200 sccm, with a preferred flow rate of between about 25 and 100 sccm.

As noted, the precursor deposition gas is introduced by second conduit 60 into collision region 65. Collision region 65 is disposed in the path of travel of the neutral free radicals of the activated species of the energy transferring gas as those activated species are directed from activation region 34 through screen 70 toward substrate 50. Neutral free radical species from activation region 34 are directed towards screen 70, concentrated to form a neutral-enriched pre-deposition medium and continue to collision region 65. In collision region 65, species within the neutral-enriched pre-deposition medium collide and interact with the precursor deposition gas so as to create a desired energized deposition medium that includes a high proportion of species conducive to the formation of a high quality thin film material on substrate 50. Interactions of neutrals with the precursor gas produce a different distribution of species from the precursor gas than do interactions of ions and ion-radicals with the precursor gas. Ions and ion-radicals generally collide at higher energies with the molecules of the precursor gas and tend to produce a higher concentration of ion and ion-radicals from the precursor gas. In the case of silane, for example, interactions of neutrals with SiH₄ produces a greater concentration of neutrals such as SiH₃, SiH₂, SiH, Si, and H in the deposition medium adjacent to substrate 50 and promote the formation of as-deposited material having fewer defects. Interactions of ions and ion-radicals with SiH₄, in contrast, produces a greater concentration of charged species such as SiH₃⁺, SiH₂⁺, SiH⁺, Si₊, and H⁺, lead to the deposition of poorer quality materials in the as-deposited state and necessitate a slow down in deposition rate to remedy defects and improve the quality.

Collision region 65 is preferably disposed at a sufficient distance from substrate 50 to insure that the species of the deposition medium created in collision region 65 will deposit uniformly over the entire surface of substrate 50 without encountering multiple collisions with either each other or stray species remaining from the activated species 34 or pre-deposition medium that may be present at the growth front. Multiple collisions of or between the preferred, neutral-enriched species of the instant deposition medium increase the likelihood of forming ions or ion-radicals adjacent to the deposition surface of substrate 50. It should also be noted that as the pressure changes from the activation region to the collision region, so does the mean-free-path length of the activated species and species of the neutral-enriched pre-deposition medium exiting screen 70. The mean-free path increases as the pressure decreases in the direction from activation region 34 to collision region 65 such that a plasma can be formed in activation region 34 and cannot be formed in collision region 65. In a preferred embodiment, the background pressure to which enclosure 12 is evacuated provides for a mean-free path of approximately 1-15 cm for neutral free radical species in the deposition medium. Therefore, by spacing the substrate a distance of 1-15 cm from the collision region, the entire surface thereof will be covered with a uniform thin film of material and the likelihood of collisions of neutral species within the deposition medium prior to deposition is minimized.

As indicated hereinabove, it is desirable to form the plasma at conditions at or near the minimum of the modified Paschen curve. In one embodiment, this objective is achieved by maintaining a pressure differential of at least a factor of five between the pressure at distal end 24a (or aperture 26) of first conduit 24 and the background pressure that exists within enclosure 12. Generally the background pressure of enclosure 12 is less than about 50 torr and preferably between 0.01 mtorr to 10 mtorr. In the preferred range of background pressure of enclosure 12, the pressure proximate distal end 24a or aperture 26 of first conduit 24 is at or below 30 torr. The flow rate of the energy transferring gas in first conduit 24 also influences the pressure differential and is generally kept in the range between 100-2000 sccm. As is known to those of skill in the art, the pressure within any given isobar decreases with increasing distance away from distal end 24a or aperture 26 of first conduit 24. Therefore, at any given power, the slope of the Paschen curve will provide a pressure-determined boundary of the activation region.

The instant invention further extends the advantages of the deposition apparatus described in the '619 application. Additional designs and improvements of a high rate deposition apparatus and methods that include the formation of a neutral-enriched deposition medium in a plasma-activated process are presented. The energy transferring gases, precursor gases, plasma activation means, principles of separation, and compositions of deposited materials described in the '619 application apply to the instant invention.

As will be described more fully hereinbelow, the instant invention provides additional avenues for controlling the deposition process of crystalline, polycrystalline, microcrystalline, nanocrystalline and amorphous materials to achieve higher quality and better performance characteristics. Placement of the collision region between the separation element and substrate in the '619 application, for example, may permit the formation ions and ion-radicals from the neutrals exiting the biased screen in the vicinity of the substrate. The instant invention considers alternative process flow schemes that may further reduce the concentration of ions and ion-radicals below the already low levels achieved in the '619 application.

In one embodiment, the method of the instant application includes the following general steps: (1) provision of an energy transferring gas (e.g. one or more of He, Ne, Ar, Kr, Xe, H₂) at transonic velocity to a plasma activation region within a deposition apparatus or chamber; (2) generation of a supply of activated species (which include ions, ion-radicals, and neutral radicals) by creating a plasma from the energy transferring gas in the plasma activation region; (3) delivery of the activated plasma species to a collision region by creating a pressure differential between the activation region and the collision region to direct the activated species of the plasma to the collision region and to maintain adequate velocity of motion to provide the activated species to the collision region without significant decay or transformation; (4) introduction of a feedstock gas including a deposition precursor into the collision region to physically and chemically interact with the activated plasma species to form a pre-deposition medium that includes ions, ion-radicals and neutrals of one or more elements intended for incorporation into a thin film material; (5) separation of charged species (ions and ion-radicals) with the pre-deposition medium from neutral species within the pre-deposition medium to form a deposition medium that is enriched in neutral species relative to the pre-deposition medium; and (6) high rate deposition of a high quality thin film material from the neutral-enriched deposition medium onto a substrate located sufficiently close to the collision region to prevent significant decay or transformation of species within the neutral-enriched deposition medium.

In this method, the precursor gas interacts with the full range of species produced in the plasma activation of the energy transferring gas. Ions, ion-radicals, and neutral radicals of the energy transferring gas collide and interact with the precursor gas to form a pre-deposition medium of the precursor gas that contains ions, ion-radicals, and neutrals. Separation of charged and uncharged species occurs only after formation of the pre-deposition medium. In the method of the '619 application, the charged species of the plasma formed from the energy transferring gas are separated from the uncharged species before the plasma is directed to the collision region to interact with the precursor gas.

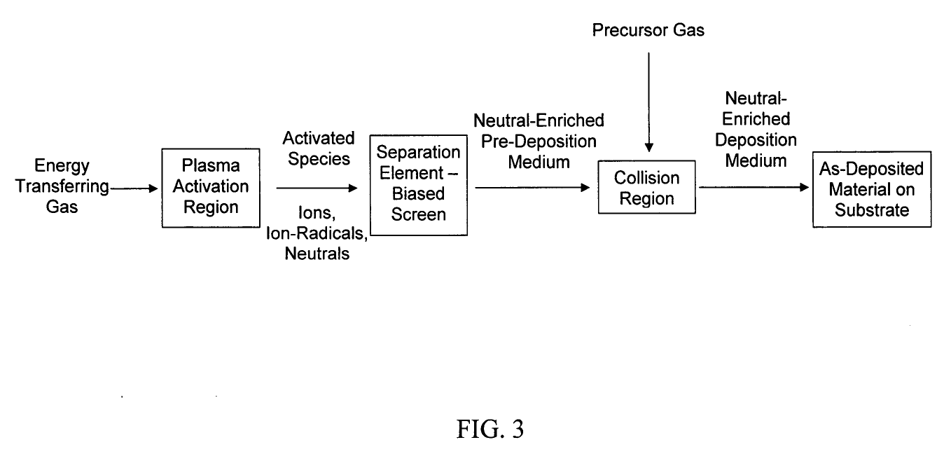

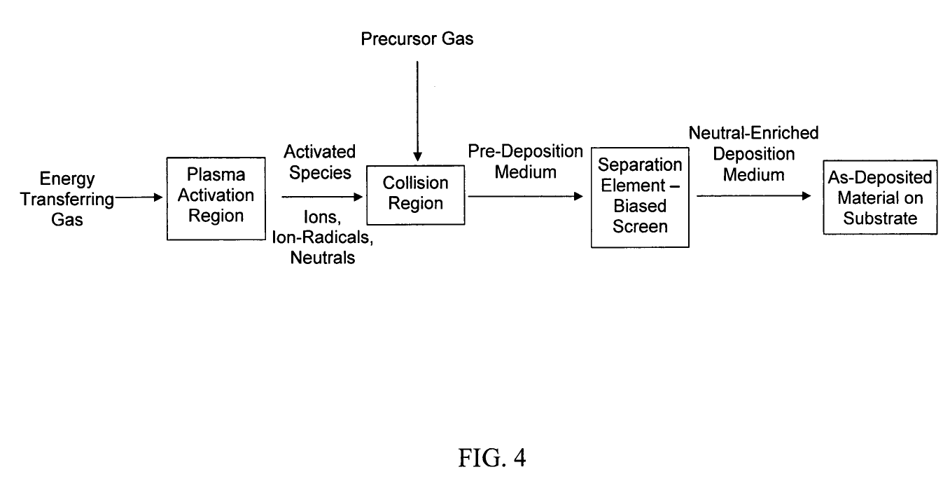

A schematic comparison of the method of the '619 application and this embodiment of the instant invention is shown in FIGS. 3 and 4. FIG. 3 depicts the general steps of the method and apparatus of the '619 application. As indicated hereinabove, the basic steps of the invention of the '619 application include: 1) providing an energy transferring gas at transonic velocity through a conduit at conditions near the minimum of the modified Paschen curve to a plasma activation region; (2) initiating a plasma from the energy transferring gas to form activated species that include ions, ion-radicals, and neutrals; (3) directing the activated species to a separation element, such as a biased screen, to preferentially reject ions and ion-radicals and preferentially pass a pre-deposition medium that is enriched with neutrals; (4) combining the neutral-enriched pre-deposition medium with a precursor gas at a collision region adjacent to a substrate to form a neutral-enriched deposition medium; and (5) depositing a thin film material from the deposition medium on the substrate.

FIG. 4 depicts the general steps of this embodiment of the instant invention. The basic steps of this embodiment include: (1) providing an energy transferring gas at transonic velocity through a conduit at conditions near the minimum of the modified Paschen curve to a plasma activation region; (2) initiating a plasma from the energy transferring gas to form activated species that include ions, ion-radicals, and neutrals; (3) delivering the activated species and a deposition precursor gas to a collision region; (4) forming a pre-deposition medium through collision and interaction of the activated species and the deposition precursor; (5) directing the pre-deposition medium to a separation element, such as a biased screen, to preferentially reject ions and ion-radicals of the pre-deposition medium and preferentially pass a deposition medium that is enriched with neutrals; and (6) directing the neutral-enriched deposition medium to a substrate and forming a thin film material thereon.

From the standpoint of an apparatus to perform the instant method, one can modify deposition apparatus 10 shown in FIG. 2 by relocating the collision region 65 to a point between cut-away section 36 of applicator 28 and screen 70. The general principles of operation, deposition apparatus, and components thereof of the instant method and apparatus follow analogously to those described hereinabove in connection with FIG. 2 and the '619 application. The energy transferring gas flows at transonic velocity through first conduit 24 (or aperture 26), preferably in choke mode and preferably exiting at conditions at or near the minimum of the modified Paschen curve. A plasma is formed from the energy transferring gas within applicator 28 and exits cut-away section 36 as a plume 34 of activated species that includes ions, ion-radicals, and neutrals. As indicated hereinabove, the plasma may be formed from electromagnetic energy, including radiofrequency energy or microwave energy. The activated species are propelled toward a collision region 65 located in front of biased screen 70. Motion of the activated species is imparted by the momentum of the transonic velocity of the energy transferring gas in first conduit 24 and the pressure differential occurring between aperture 26 of first conduit 24 and the background pressure of enclosure 12.

Second conduit 60 delivers a precursor gas to the collision region to collide with and otherwise interact with activated species of plume 34. Depending on the pressure at the collision region, the activated species may or may not be in a plasma state when they collide with the precursor gas. If the activated species are in the form of a plasma, biased screen 70 is positioned sufficiently far away from the collision region to exist outside the boundaries of the plasma. The activated species of the energy transferring gas interact with the precursor gas to form a pre-deposition medium comprising ions, ion-radicals, and neutral radicals that include elements or fragments of the precursor gas. The pre-deposition medium further includes ions, ion-radicals, and neutral radicals of the energy transferring gas and mixed species that may combine elements or fragments of the energy transferring gas and elements or fragments of the precursor gas.

The pre-deposition medium is propelled toward electrically-biased screen 70, which preferentially rejects ions and ion-radicals and preferentially passes neutral radicals to form a neutral-enriched deposition medium. The neutral-enriched deposition medium exits electrically-biased screen 70 adjacent to substrate 50 and forms a thin film material in an as-deposited state on the surface thereof. Substrate 50 is positioned sufficiently close to electrically-biased screen 70 to permit the species of the neutral-enriched deposition medium to reach the deposition surface without undergoing extensive collisions or transformation. Enrichment of the deposition medium with neutral species permits the formation of as-deposited material on substrate 50 having a low concentration of intrinsic defects. The deposition medium has a higher proportion of neutral species and a lower proportion of ions and ion-radicals than the pre-deposition medium. Preferably the fraction of ionized gaseous species (ions and ion-radicals) is reduced by at least 50%, more preferably by at least 75% and most preferably by at least 90%.

In another embodiment, the method of the instant application includes the following general steps: (1) provision of a mixture of an energy transferring gas (e.g. one or more of He, Ne, Ar, Kr, Xe, H₂) and a deposition precursor gas at transonic velocity to a plasma activation region within a deposition apparatus or chamber; (2) generation of a pre-deposition medium comprising a supply of activated species (which include ions, ion-radicals, and neutral radicals) by creating a plasma from the mixture of the energy transferring gas and precursor gas in the plasma activation region; (3) delivery of the activated plasma species within the pre-deposition medium to a separation element to separate charged species (ions and ion-radicals) of the pre-deposition medium from the uncharged species of the pre-deposition medium to form a deposition medium that is enriched in neutral species; (4) delivery of the pre-deposition medium to the separation element and the neutral-enriched deposition medium to a substrate by creating a pressure differential between the plasma activation region and the substrate to direct the activated species of the pre-deposition medium to the separation element and the neutral-enriched species of the deposition medium exiting the separation element to the substrate, and to maintain adequate velocity of motion to provide the species of the neutral-enriched deposition medium to the substrate without significant decay or transformation; and (5) high rate deposition of a high quality thin film material from the neutral-enriched deposition medium onto the substrate.

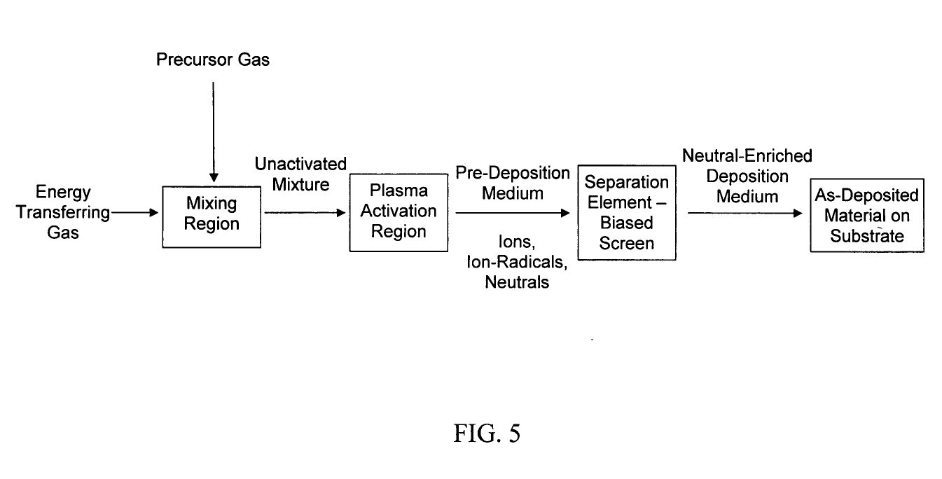

FIG. 5 depicts the general steps of this embodiment of the instant invention. The basic steps of this embodiment include: (1) providing an energy transferring gas and a precursor gas to a mixing region to mix the energy transferring gas and precursor gas; (2) delivering the mixture at transonic velocity through a conduit at conditions near the minimum of the modified Paschen curve to a plasma activation region; (3) initiating a plasma from the mixture to form a pre-deposition medium comprising activated species that include ions, ion-radicals, and neutrals; (4) directing the pre-deposition medium to a separation element, such as a biased screen, to preferentially reject ions and ion-radicals of the pre-deposition medium and preferentially pass a deposition medium that is enriched with neutrals; and (6) directing the neutral-enriched deposition medium to a substrate and forming a thin film material thereon.

From the standpoint of an apparatus to perform the instant method, one can modify deposition apparatus 10 shown in FIG. 2 by removing the collision region 65 and replacing it with a mixing region at a point before plasma activation region 34. The mixing region may be located outside of or within enclosure 12. The general principles of operation, deposition apparatus, and components thereof of the instant method and apparatus follow analogously to those described hereinabove in connection with FIG. 2 and the '619 application. The energy transferring gas and precursor gas are mixed, introduced to conduit 24 as an unactivated mixture, and caused to flow at transonic velocity through first conduit 24 (or aperture 26), preferably in choke mode and preferably exiting at conditions at or near the minimum of the modified Paschen curve. A plasma is formed from the mixture within applicator 28 and exits cut-away section 36 as a plume 34 of activated species that includes ions, ion-radicals, and neutrals formed from the mixture of the energy transferring gas and the precursor gas. As indicated hereinabove, the plasma may be formed from electromagnetic energy, including radiofrequency energy or microwave energy.

In this embodiment, the precursor gas is directly activated to the plasma state and interacts with the energy transferring gas in the plasma state to form a pre-deposition medium. The pre-deposition medium comprises ions, ion-radicals, and neutral radicals that include elements or fragments of the precursor gas, the energy transferring gas, and mixed species that may combine elements or fragments of the energy transferring gas and elements or fragments of the precursor gas.

The pre-deposition medium is propelled toward electrically-biased screen 70. Motion of the pre-deposition medium is imparted by the momentum of the transonic velocity of the mixture in first conduit 24 and the pressure differential maintained between aperture 26 of first conduit 24 and the background pressure of enclosure 12. Electrically-biased screen 70 is positioned sufficiently far away from the cut-away section 36 to exist outside the boundaries of the plasma to avoid etching or degradation. Electrically-biased screen 70 preferentially rejects ions and ion-radicals and preferentially passes neutral radicals to form a neutral-enriched deposition medium. The neutral-enriched deposition medium exits electrically-biased screen 70 adjacent to substrate 50 and forms a thin film material in an as-deposited state on the surface thereof. Substrate 50 is positioned sufficiently close to electrically-biased screen 70 to permit the species of the neutral-enriched deposition medium to reach the deposition surface without undergoing extensive collisions or transformation. Enrichment of the deposition medium with neutral species permits the formation of as-deposited material on substrate 50 having a low concentration of intrinsic defects.

In a further aspect, the instant invention provides a process control system and method. The process control system and method includes a diagnostic element and a feedback control element. The diagnostic element permits sensing of the distribution of species at various points in the deposition process and the feedback control element receives process data from the diagnostic element, compares the process data to data for pre-determined optimum conditions, and adjusts process conditions as necessary to insure that optimal conditions are maintained in real time. The process control system and method is applicable to all embodiments of the instant invention and the embodiments disclosed in the '619 application, including the embodiments depicted in FIGS. 2-5 hereinabove.

The diagnostic element includes means for sensing the composition of the energy transferring gases, the precursor gases, the activated species, the plasmas, the ionized mixtures, the pre-deposition media, the deposition media, and/or the as-deposited thin film materials of the instant invention. Detection of the composition at various points in the process may occur by placing sensors within enclosure 12 or at delivery points outside of enclosure 12. The diagnostic element may include chemical or elemental sensors for detecting the composition and purity of the energy transferring gas or precursor gas. Charged species (ions and ion-radicals) may be detected by electrostatic or magnetic means. Neutral radicals and ion-radicals may be sensed by means capable of detecting the presence of free electrons, such as electron spin resonance. In one embodiment, the diagnostic element includes a mass spectrometer for detecting the identify of and relative proportions of ions, ion-radicals, and neutrals at various points in the process, including in the plasma activation region, the collision region, before and after the separation element, and in the region adjacent to the substrate during thin film growth.

The diagnostic element may also include a unit for probing the composition or characteristics of the as-deposited thin film material. An optical probe may be used to assess the quality of the as-deposited thin film material since the presence of defects in the as-deposited material may be reflected in its optical properties. The optical probe may be a conventional broadband or monochromatic light source (e.g. tungsten-halogen lamp), a light emitting diode, or a laser. The optical probe may be an absorption or transmission technique, a light scattering method, or a reflection method. Ellipsometry provides information about the optical constants (refractive index, absorption coefficient, dielectric constant) of the as-deposited material. Optical absorption spectroscopy provides information about the band gap and the presence of certain midgap defect states. Light scattering techniques can detect the presence of certain midgap defects. The dihydride defect in amorphous silicon, for example, has an intense fingerprint signature at ˜2100 cm⁻¹ that is detectable in Raman scattering. The thin film material preferably has a non-single crystal microstructure with a midgap defect concentration of less than 1×10¹⁶ cm⁻³. More preferably, the material has a midgap defect concentration of less than 1×10¹⁵ cm⁻³. Most preferably, the material has a midgap defect concentration of less than 5×10¹⁴ cm⁻³.

Information obtained from the diagnostic element is transmitted to a feedback control element. The feedback control element permits real-time control of process conditions based on information provided by the diagnostic element. Calibrations and correlations of process conditions with the quality of the as-deposited film can be developed and utilized by the feedback control element to optimize process conditions during deposition. As an example, the optical constants, optical absorption, transmittance, reflection, luminescence, and light scattering characteristics of high quality amorphous silicon and other amorphous semiconductors are known and can be compared to measurements made in real time by the instant optical diagnostic unit to assess the quality of as-deposited material. Correlations of process conditions with optical properties can be developed and incorporated into the feedback control element to adjust process conditions as needed. Similar correlation can be developed from mass spectrometry or other data that characterizes the identity and concentration of ions, ion-radicals, and neutrals as a function of position in a deposition apparatus.

The calibrations and correlations may include target conditions for the distribution of species in the plasma, pre-deposition medium, and deposition medium. The feedback control element receives real-time data from the diagnostic element and compares this data to target conditions known to correlate with high quality as-deposited material. If the real-time data deviates from the target conditions to an unacceptable degree, the feedback control element includes the capability to adjust process conditions to better conform to the target conditions. In one embodiment, the feedback control element adjusts the composition of the deposition medium so that SiH₃ is the most prevalent neutral species.

The feedback control element can adjust the mass flow rate of the energy transferring gas or precursor gas as well as the presence and amount of diluent gas. The feedback control element can also control the energy and frequency of electromagnetic radiation used to form plasmas in the instant deposition apparatus. The motion of the plasma, activated species, the pre-deposition medium, and deposition medium of a particular process can be controlled by controlling the background pressure in the deposition enclosure and the pressure differential across the deposition apparatus. A higher pressure differential provides greater velocity and energy of motion. Control of the pressure also influences the mean-free path of motion for ions, ion-radicals, and neutrals and permits the ability to regulate the extent of collisions between species of the pre-deposition medium and deposition medium before reaching the growth surface at the substrate.

The feedback control element can also regulate the electrical bias of the separation element. The magnitude and polarity of the bias applied across the separation element influences the strength of attraction or repulsion of the separation element with activated species in the form of ions and ion-radicals, whether in a plasma or non-plasma state (such as a gas phase mixture of ionized species), and thus provides selective control over the distribution of activated species that are rejected and passed by the screen. In some embodiments, the instant invention includes a plurality of separation elements. Use of multiple electrically-biased screens permits finer control over the distribution of species that form the neutral-enriched medium that is delivered to the growth front. In one embodiment, a gradient of bias potential is distributed over a series of separation elements. The gradient may be ascending or descending. In another embodiment, an alternating pattern of bias potential is distributed over a series of separation elements. The polarity, for example, may alternate from positive to negative to positive to negative etc. In another embodiment, the polarity and/or magnitude of the bias potential may vary in time. In another embodiment, the separation elements are mounted within a servo-control system so that spacing between separation elements, between a separation element and the plasma activation region, or between a separation element and the substrate may be varied. The different degrees of freedom in controlling the potential, distribution or pattern of potential, and relative spacing of the separation elements affords great control over the identity and relative proportion of species within the pre-deposition medium and the deposition medium as well as control over the lifetime of the different species through the mean-free path.

In another embodiment, the feedback control element regulates the temperature of the substrate. The temperature of the substrate influences the structure and intrinsic defect concentration of the as-deposited material. Higher substrate temperatures, for example, tend to improve the quality of the as-deposited material by annealing defects. Higher substrate temperatures, however, also tend to diminish the deposition rate by promoting volatilization of material from the surface. The instant feedback control element can make judicious use of temperature by monitoring one or more intrinsic defects of the as-deposited material (e.g. via an optical probe) and temporarily increasing the substrate temperature in response to a detected increase in defect concentration.

In addition to stationary substrates, the methods and principles of the instant invention further extend to mobile, continuous web depositions as well as to deposition processes that require multiple deposition chambers. In these embodiments, a web of substrate material may be continuously advanced through a succession of one or more operatively interconnected, environmentally protected deposition chambers, where each chamber is dedicated to the deposition of a specific layer of semiconductor alloy material onto the web or onto a previously deposited layer situated on the web. By making multiple passes through the succession of deposition chambers, or by providing an additional array of deposition chambers, multiple stacked cells of various configurations may be obtained and the benefits arising from the instant neutral-enriched deposition method may be achieved for multiple compositions within a multilayer device.

An important photovoltaic device, for example, is the triple junction solar cell, which includes a series of three stacked n-i-p devices with graded bandgaps on a common substrate. The graded bandgap structure provides more efficient collection of the solar spectrum. In making an n-i-p photovoltaic device, a first chamber is dedicated to the deposition of a layer of an n-type semiconductor material, a second chamber is dedicated to the deposition of a layer of substantially intrinsic (i-type) amorphous semiconductor material, and a third chamber is dedicated to the deposition of a layer of a p-type semiconductor material. The process can be repeated by extending the web to six additional chambers to form a second and third n-i-p structure on the web. Bandgap grading is achieved by modifying the composition of the intrinsic (i-type) layer. In one embodiment, the highest bandgap in the triple junction cell results from incorporation of amorphous silicon as the intrinsic layer in one of the n-i-p structures. Alloying of silicon with germanium to make amorphous silicon-germanium alloys leads to a reduction in bandgap. In one embodiment, the second and third n-i-p structures of a triple junction cell include intrinsic layers comprising SiGe alloys having differing proportions of silicon and germanium. Multiple precursor gases may be delivered simultaneously to the instant deposition apparatus to form alloys. Bandgap modification may also be achieved through control of the microstructure of the intrinsic layer. Polycrystalline silicon, for example, has a different bandgap than amorphous silicon and multilayer stacks of various structural phases may be formed with the instant continuous web apparatus.

The instant invention allows for a tremendous increase in the throughput and film formation rate in continuous web deposition processes. With the invention, the web speed can be increased without sacrificing the quality of the deposited thin film layers by minimizing intrinsic defects through the principles of the neutral-enriched deposition process described hereinabove. The instant invention permits an expansion of the current 30 MW manufacturing capacity to the GW regime through an increase in deposition rate from ˜1-5 Å/s available from the current art. Deposition rates up to 300 Å/s may be achieved using the principles of the present invention. In one embodiment, deposition rates of 20-50 Å/s are achieved. In another embodiment, deposition rates of 50-150 Å/s are achieved. In still another embodiment, deposition rates of 150-300 Å/s are achieved.

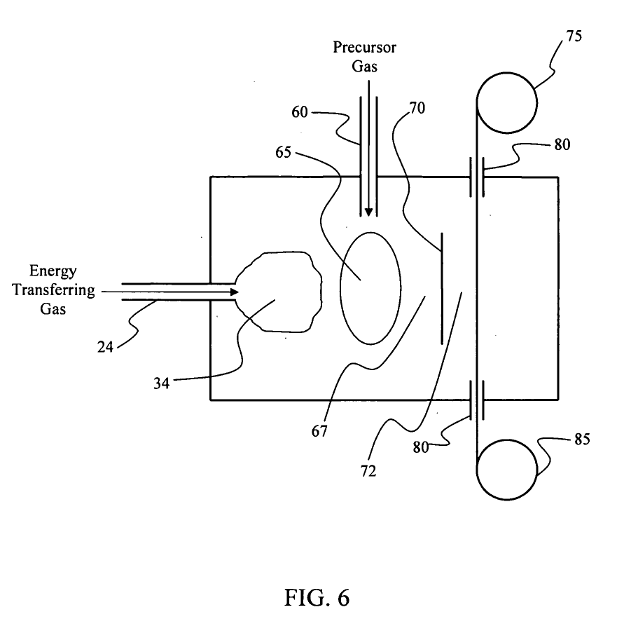

FIG. 6 depicts a continuous web deposition apparatus consistent with the embodiment shown in FIG. 3. The deposition apparatus 10 includes mobile, continuous web substrate 50 that is dispensed by payoff roller 75, enters and exits enclosure 12 through gas gates 80, and is picked up by take up roller 85. Continuous substrate 50 may be formed from steel, a plastic (e.g. Mylar or Kapton), or other durable material. As substrate 50 passes into and out of deposition apparatus 10, a thin film material may be deposited thereon according to the principles described hereinabove. The energy transferring gas enters conduit 24. A plasma of the energy transferring gas is formed plasma activation region 34 and interacts with a precursor gas in collision region 65 to form a pre-deposition medium in region 67. The pre-deposition medium passes through electrically-biased screen 70 to form a deposition medium in region 72 and a thin film material is formed on web substrate 50 as it passes through enclosure 12. A plurality of enclosures of the type 12 may be connected in series for the continuous formation of multi-layered devices. The embodiment shown in FIG. 5 may be similarly adapted to continuous web and multiple chamber deposition processes.

Those skilled in the art will appreciate that the methods and designs described above have additional applications and that the relevant applications are not limited to the illustrative examples described herein. The present invention may be embodied in other specific forms without departing from the essential characteristics or principles as described herein. The embodiments described above are to be considered in all respects as illustrative only and not restrictive in any manner upon the scope and practice of the invention. It is the following claims, including all equivalents, which define the true scope of the instant invention.

We claim:

1. An apparatus for forming a deposition medium for deposition on a substrate comprising:
a deposition chamber, said deposition chamber including a plasma activation region and a collision region;
means for introducing an energy transferring gas into said plasma activation region, said plasma activation region forming a plasma from said energy transferring gas, said plasma including ions, ion-radicals, and neutral radicals;
means for directing said ions, ion-radicals, and neutral radicals of said plasma to said collision region;
means for introducing a precursor gas into said collision region, said precursor gas and said ions, ion-radicals, and neutral radicals of said plasma interacting in said collision region to form a pre-deposition medium, said pre-deposition medium including ions, ion-radicals, and neutral radicals; and
a separation element adapted to exclude a portion of said ions and ion-radicals of said pre-deposition medium to form a deposition medium for deposition on a substrate.

2. The apparatus of claim 1, wherein said means for introducing said energy transferring gas into said plasma activation region introduces said energy transfer gas at a transonic velocity.

3. The apparatus of claim 1, wherein said plasma activation region includes means for activating a plasma from said energy transferring gas, said plasma activation means including means for delivering electromagnetic energy to said energy transferring gas.

4. The apparatus of claim 3, wherein said electromagnetic energy is radiofrequency energy or microwave energy.

5. The apparatus of claim 1, wherein said collision region is disposed between said plasma activation region and said separation element;

6. The apparatus of claim 1, wherein said means for directing said ions, ion-radicals, and neutral radicals of said plasma to said collision region comprises means for establishing a pressure differential between said plasma activation region and said collision region, said pressure differential including a high pressure at said plasma activation region and a low pressure at said collision region.

7. The apparatus of claim 1, wherein said pre-deposition medium is a mixture of said ions, ion-radicals, and neutral radicals in a non-plasma state.

8. The apparatus of claim 1, wherein said separation element comprises a first electrically-biased screen having a first polarity.

9. The apparatus of claim 8, wherein said separation element further comprises a second electrically-biased screen having a second polarity.

10. The apparatus of claim 1, further comprising a substrate disposed adjacent to said deposition medium, said deposition medium forming a thin film material on said substrate.

11. The apparatus of claim 10, wherein said substrate is in motion.

12. The apparatus of claim 11, wherein said substrate is a continuous web.

13. The apparatus of claim 10, wherein said separation element is disposed between said collision region and said substrate.

14. The apparatus of claim 1, further comprising a process control system, said process control system including a diagnostic unit for monitoring conditions within the interior of said apparatus.

15. The apparatus of claim 14, wherein said diagnostic unit includes means for sensing the composition of said energy transferring gas, said precursor gas, said plasma, said pre-deposition medium or said deposition medium.

16. The apparatus of claim 15, wherein said means for sensing said composition includes a mass spectrometer.

17. The apparatus of claim 14, further comprising a substrate disposed adjacent to said deposition medium, said deposition medium forming a thin film material on said substrate.

18. The apparatus of claim 17, wherein said diagnostic unit includes means for sensing the composition of or concentration of defects in said thin film material.

19. The apparatus of claim 18, wherein said means for sensing said composition or defect concentration is an optical means.

20. The apparatus of claim 14, wherein said process control system further includes a feedback control element, said feedback control element receiving information from said diagnostic unit and regulating the conditions within said apparatus in response thereto.

21. The apparatus of claim 20, wherein said feedback control element includes means for controlling the energy or frequency of said plasma.

22. The apparatus of claim 20, wherein said feedback control element includes means for controlling the flow rate of said energy transferring gas or said precursor gas.

23. The apparatus of claim 20, wherein said separation element is electrically biased and said feedback control element includes means for controlling said electrical bias.

24. The apparatus of claim 20, wherein said feedback control element stores data corresponding to optimized conditions within said apparatus, said feedback control element comparing said information received from said diagnostic unit with said optimized conditions.

25. The apparatus of claim 24, wherein said feedback control element adjusts the conditions within said apparatus in response to said comparison, said adjustment of said conditions decreasing the deviation of said conditions from said optimized conditions.

26. The apparatus of claim 20, wherein said feedback control element includes means for modifying the pressure differential between said plasma activation region and said separation element.
